(19) United States
(12) Patent Application Publication
(10) Pub. No.: US 2026/0132301 A1
(43) Pub. Date: May 14, 2026

(54) Ink Composition, Electronic Apparatus and Manufacturing Method of the Same

(71) Applicants: Samsung Display Co., Ltd., Yongin-si (KR); Chemtronics Co., Ltd., Sejong (KR)

(72) Inventors: Yiseop Shim, Yongin-si (KR); Younhoe Kim, Sejong (KR); Seungyun Baik, Sejong (KR); Taejun Kim, Sejong (KR); Haebong Yi, Sejong (KR); Su Jeong Kim, Yongin-si (KR); Yun-Hee Park, Yongin-si (KR); Duckjong Suh, Yongin-si (KR); Donggeun Shin, Yongin-si (KR); Hyebeom Shin, Yongin-si (KR); Hyunseung Lee, Yongin-si (KR); Kyuwon Cho, Yongin-si (KR)

(73) Assignees: Samsung Display Co., Ltd., Yongin-si (KR); Chemtronics Co., Ltd., Sejong (KR)

(21) Appl. No.: 19/308,512

(22) Filed: Aug. 25, 2025

(30) Foreign Application Priority Data
Nov. 8, 2024 (KR) 10-2024-0157778

(51) Int. Cl. C09D 11/101; C09D 11/037; C09D 11/107; H10K 59/12; H10K 59/80

(52) U.S. Cl. CPC C09D 11/101; C09D 11/037; C09D 11/107; H10K 59/1201; H10K 59/8792

(57) ABSTRACT

Provided is an ink composition including a base resin, a photo initiator and a mill base including a pigment, a dispersant, and a (meth)acrylate monomer. The (meth)acrylate monomer includes a first monomer having a first viscosity, and a second monomer having a second viscosity greater than the first viscosity, and thus the ink composition may have excellent dispersibility, storage stability, and processibility.

### CROSS-REFERENCE TO RELATED APPLICATIONS

This U.S. non-provisional patent application claims priority under 35 U.S.C. § 119 of Korean Patent Application No. 10-2024-0157778, filed on Nov. 8, 2024, the entire contents of which are hereby incorporated by reference.

### BACKGROUND

The present disclosure herein relates to an ink composition and an electronic apparatus, and a method of manufacturing the same, and more specifically to an ink composition form a light-shielding layer, and an electronics device including the light-shielding layer and a method of manufacturing the same.

Various display devices used in multimedia apparatuses such as televisions, smartphones, tablet computers, and game consoles, have been developed. The display device may be a rigid type, or a flexible type that is foldable, rollable, bendable, allowing for various changes in shape.

In the display device in various shapes, members for reducing reflection of external light are being used in order to improve display quality. However, in the development of members for improving reflection, it is necessary to sufficiently absorb external light to exhibit excellent optical properties, while simultaneously ensuring excellent durability and reliability according to the usage patterns of the display device.

### SUMMARY

The present disclosure provides an ink composition having improved dispersibility, storage stability, and processibility.

The present disclosure also provides an electronic apparatus including a light-shielding layer having excellent in light-shielding property, durability and adhesion.

The present disclosure also provides a method of manufacturing an electronic apparatus having improved reliability and processibility.

An embodiment of the inventive concept provides an ink composition including a base resin, a photo initiator, and a mill base including a pigment, a dispersant, and a (meth)acrylate monomer, and the (meth)acrylate monomer includes a first monomer having a first viscosity, and a second monomer having a second viscosity greater than the first viscosity.

In an embodiment, with respect to the total amount 100 wt % of the mill base, the mill base may include about 5 wt % to about 30 wt % of the pigment, about 2 wt % to about 10 wt % of the dispersant, about 30 wt % to about 45 wt % of the first monomer, and about 30 wt % to about 45 wt % of the second monomer.

In an embodiment, a difference between the first viscosity and the second viscosity may be about 100 cP to about 5000 cP.

In an embodiment, the pigment may include carbon black.

In an embodiment, the ink composition may include no solvent.

In an embodiment, the first monomer may include 1,6-hexanediol diacrylate, and the second monomer may include pentaerythritol tetraacrylate.

In an embodiment, the ink composition may further include a photo polymerizable monomer including two or more polymerizable groups, a coupling agent, and an additive including at least one among an antistatic agent, a leveling agent, and a defoamer.

In an embodiment, with respect to the total amount 100 wt % of the ink composition, the ink composition may include about 25 wt % to about 60 wt % of the base resin, about 5 wt % to about 15 wt % of the photo initiator, about 5 wt % to about 20 wt % of the mill base, about 25 wt % to about 60 wt % of the photopolymerizable monomer, about 0.5 wt % to about 3 wt % of the coupling agent, and about 0.2 wt % to about 4 wt % of the additive.

In an embodiment, the second monomer may be the same as the polymerizable monomer.

In an embodiment, the base resin may have a weight average molecular weight of about 5000 to about 50000.

In an embodiment of the inventive concept, an electronic apparatus includes a display module, a light-shielding layer disposed below the display module and formed using an ink composition, and a housing accommodating the display module.

In an embodiment, the light-shielding layer may have a thickness of about 9 m to about 16 m.

In an embodiment, the display module may include a base layer and a display element layer disposed on the base layer and including a light-emitting element, and the light-shielding layer is directly disposed below the base layer.

In an embodiment, the light-shielding layer may be a single layer formed using the ink composition.

In an embodiment of the inventive concept, a method of manufacturing an electronic apparatus includes providing a display module, and providing an ink composition on a rear surface of the display module to form a light-shielding layer.

In an embodiment, the method of manufacturing an electronic apparatus may further include preparing the ink composition, the preparation of the ink composition may include milling a mixture of the pigment, the dispersant, and the first monomer to prepare a first mill base composition, preparing a second mill base composition including the second monomer, and mixing the first mill base composition and the second mill base composition to prepare the mill base.

In an embodiment, the forming of the light-shielding layer may include providing the ink composition on the rear surface of the display module to form a preliminary light-shielding layer, and photo-curing the preliminary light-shielding layer.

In an embodiment, the providing of the ink composition may be performed by a screen-printing method.

In an embodiment, the display module may include a base layer, and a display element layer disposed on the base layer and including a light-emitting element, and the light-shielding layer may be directly formed below the base layer.

In an embodiment, the base layer may include a glass substrate, before the forming of the light-shielding layer, etching a bottom surface of the base layer spaced apart from the display element layer may be further included, and in the forming of the light-shielding layer, the ink composition may be applied onto the etched bottom surface of the base layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view illustrating an electronic apparatus according to an embodiment of the inventive concept;

FIG. 2 is an exploded perspective view of an electronic apparatus according to an embodiment of the inventive concept;

FIG. 3 is a block diagram of an electronic device according to an embodiment.

FIG. 4 illustrates schematic views of electronic devices according to various embodiments.

FIG. 5 is a cross-sectional view of a display device according to an embodiment of the inventive concept;

FIG. 6 is an enlarged cross-sectional view illustrating a portion of a display device according to an embodiment of the inventive concept;

FIG. 7 is a flow chart showing a method of manufacturing an electronic apparatus according to an embodiment of the inventive concept;

FIG. 8 is a flow chart showing some processes of preparing ink composition according to an embodiment of the inventive concept;

FIG. 9A to FIG. 9G are each a cross-sectional view showing some processes among a method of manufacturing an electronic apparatus according to an embodiment of the inventive concept;

FIG. 10A is an image of a display device including a light-shielding layer in Comparative Example, as captured by an infrared camera; and

FIG. 10B is an image of a display device including a light-shielding layer in Example, as captured by an infrared camera.

### DETAILED DESCRIPTION

Hereinafter, embodiments of the inventive concept will be described with reference to the accompanying drawings.

In this specification, it will be understood that when an element (or a region, a layer, a portion, or the like) is referred to as being “on”, “connected to” or “coupled to” another element, it may be directly disposed on/connected to/coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms have relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

In this specification, when an element is referred to as being “directly disposed on” another layer, film, region, plate, etc., there are no intervening layer, film, region, plate, etc., present. For example, the wording “directly disposed” means that an additional member such as an adhesive member, or the like may not be used between two layers or two members.

Unless otherwise defined, all terms (including technical and scientific terms) used herein have the same meaning as commonly understood by one ordinary skilled in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term of a “monomer” has the same meaning. The monomer in this disclosure means a compound that is distinct from an oligomer and a polymer and has a weight average molecular weight of about 1000 or less. As used herein, a “photopolymerizable functional group” may mean a functional group participating in polymerization, such as a double bond, a (meth)acrylate group, and an epoxy group.

As used herein, the term “(meth)acrylate” indicates acrylate and methacrylate, “(meth)acryl” indicates acryl and methacryl, and “(meth)acryloyl” indicates acryloyl and methacryloyl.

Hereinafter, an electronic apparatus according to an embodiment of the inventive concept will be described with reference to the accompanying drawings.

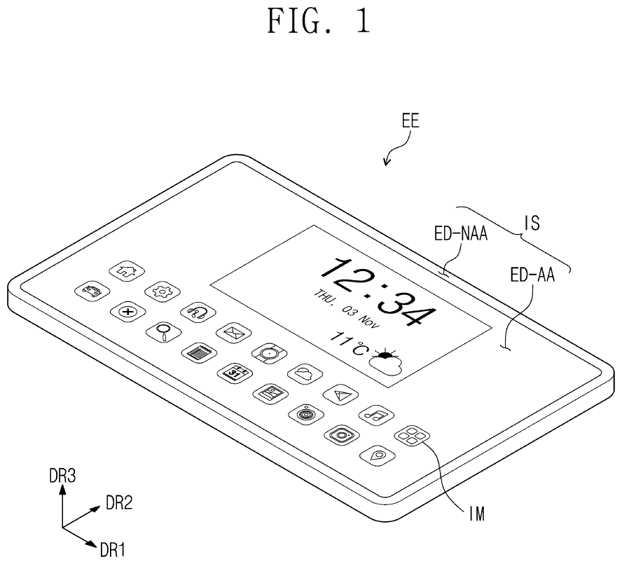

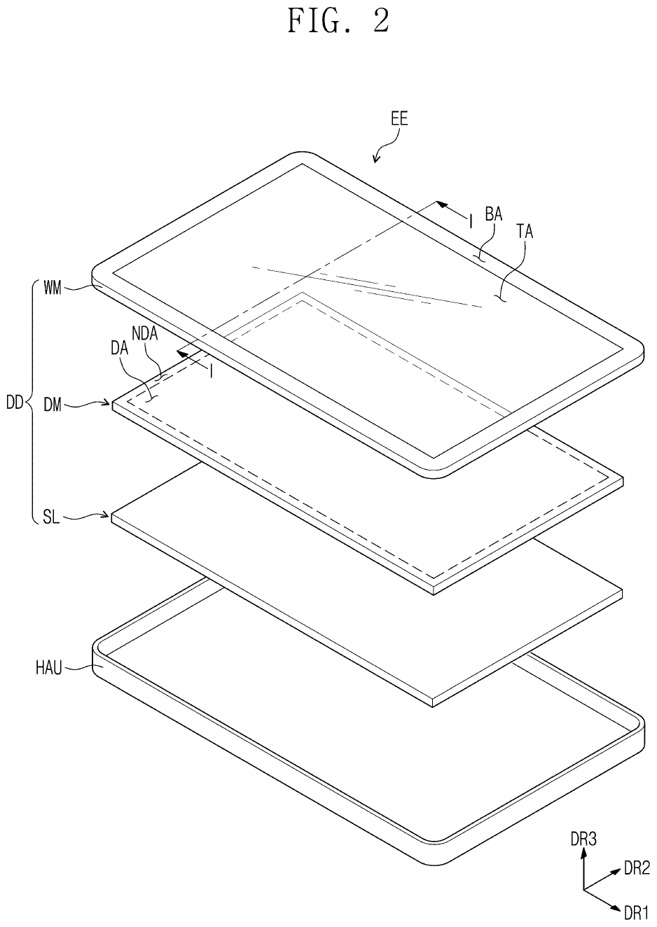

FIG. 1 is a perspective view of an electronic apparatus according to an embodiment of the inventive concept. FIG. 2 is an exploded perspective view of an electronic apparatus according to an embodiment of the inventive concept.

An electronic apparatus EE according to an embodiment may be a display device activated in response to electrical signals and displaying an image. The electronic apparatus EE may include various embodiments. For example, the electronic apparatus EE may include, in addition to a large-sized device such as televisions, outdoor billboards, a medium-sized device such as monitors, mobiles, tablet computers, navigations, and game consoles. The embodiments of the electronic apparatus EE are suggested as examples, are not limited to any one as long as they are not departing from the scope of the inventive concept.

In FIG. 1 and the following drawings, a first direction DR1 to a third direction DR3 are illustrated, and directions indicated by the first to third directions DR1, DR2, and DR3, which are described in the present specification, are relative concepts, and may be converted to other directions.

As used herein, a thickness direction of the electronic apparatus EE may be parallel to the third direction DR3, which is a normal direction to a plane defined by the first direction DR1 and the second direction DR2. As used herein, a front surface (or top surface) and a rear surface (or bottom surface) of members constituting the electronic apparatus EE may be defined on the basis of the third direction DR3.

The electronic apparatus EE may display an image IM in the third direction DR3 through a display surface IS parallel to the plane defined by the first direction DR1 and the second direction DR2. The third direction DR3 may be parallel to a normal direction of the display surface IS. The display surface IS on which the image IM is displayed may correspond to a front surface of the electronic apparatus EE. The image IM may include a still image in addition to a dynamic image. FIG. 1 illustrates the exemplified image IM in which icon images are illustrated.

As used herein, the term “in a plane” may be defined as viewed from the third direction DR3. As used herein, the term “on a cross-section” may be defined as viewed from the first direction DR1 or the second direction DR2. Directions indicated by the first to third directions DR1, DR2, and DR3 are relative concepts, and may be converted to other directions.

FIG. 1 exemplary illustrates the electronic apparatus EE having a flat-type display surface IS. However, a type of the display surface IS of the electronic apparatus EE is not limited thereto, but may be curved, or three-dimensional.

The electronic apparatus EE may be flexible. The term“flexible” means flexible property and may encompass structures ranging from fully foldable to bendable at a several nanometers level. For example, the flexible electronic apparatus EE may include a curved electronic apparatus or a foldable electronic apparatus.

The display surface IS of the electronic apparatus EE may include an active region ED-AA and a peripheral region ED-NAA. A user may view an image IM through the active region ED-AA. In an embodiment, illustrated in FIG. 1 and the like, although the active region ED-AA is illustrated to have a rectangular shape, this is merely for illustrative purpose, and the active region ED-AA may have various shapes.

The peripheral region ED-NAA may be a non-display portion that displays no image IM. The peripheral region ED-NAA may have a predetermined color and block light. The peripheral region ED-NAA may be adjacent to the active region ED-AA. For example, the peripheral region ED-NAA may be disposed on an outer edge of at least one side of the active region ED-AA, and the peripheral region ED-NAA may surround the active region ED-AA. However, this is illustrated for illustrative purposes, and the peripheral region ED-NAA may be adjacent to only one side of the active region ED-AA, or may be disposed on side rather than front of the electronic apparatus EE, but is not limited thereto, and the peripheral region ED-NAA may be omitted.

The peripheral region ED-NAA according to an embodiment may detect external input applied from the outside. The external input may have various forms such as pressure, temperature, light, provided from the outside. The external input may include an external input applied to the electronic apparatus EE at close range (e.g., hovering) as well as input by a touch (e.g., touch by user's hand or by a pen).

Referring to FIG. 2, the electronic apparatus EE may include a display device DD and a housing HAU. The display device DD may include a display module DM, a window WM disposed on the display module DM, and a light-shielding layer SL disposed below the display module DM. The display device DD may combine to the housing HAU to define external appearance of the electronic apparatus EE. The housing HAU may provide an internal space which is capable of accommodating members such as the display module DM.

The window WM may be disposed on the display module DM. The window WM may protect the display module DM from an external impact. A front surface of the window WM may correspond to the above-described display surface IS of the electronic apparatus EE. The front surface of the window WM may include a transmission region TA and a bezel region BA.

The transmission region TA of the window WM may be an optically transparent region. The window WM may transmit a provided image from the display module DM through the transmission region TA, and the user may view the corresponding image. The transmission region TA may correspond to the active region ED-AA of the electronic apparatus EE.

The window WM may include an optically transparent insulation material. For example, the window WM may include glass, sapphires, or plastics. The window WM may include a single-, or multi-layered structure. The window WM may further include functional layers such as an anti-fingerprint layer, a phase control layer, and a hard coating layer, disposed on an optically transparent substrate.

The bezel region BA of the window WM may be provided as a region where a material including a predetermined color is deposited, coated, or printed. The bezel region BA of the window WM may prevent one configuration of the display module DM located overlapping the bezel region BA from being viewed to the outside. The bezel region BA may correspond to the peripheral region ED-NAA of the electronic apparatus EE.

The display module DM may display an image in response to electrical signals. The display module DM may include a display region DA, and a non-display region NDA adjacent to the display region DA.

The display module DM may correspond to the active region ED-AA of the electronic apparatus EE. The display region DA may be a region activated in response to electrical signals. The display region DA may be a region displaying an image provided from the display module DA. The display region DA of the display module DM may correspond to the above-described transmission region TA. As used herein, “a region/portion corresponds to a region/portion” means that “the region/portion overlaps each other.” and is not limited to the fact that the display region DA has the same area and/or same shape. The image displayed in the display region DA may be viewed from the outside through the transmission region TA.

The non-display region NDA may be adjacent to the display region DA. For example, the non-display region NDA may surround the display region DA. However, an embodiment of the inventive concept is not limited thereto, and the non-display region NDA may be defined as various shapes. The non-display region NDA may correspond to the peripheral region ED-NAA of the electronic apparatus EE. The non-display region NDA may be a region in which driving circuit for driving a display region DA, various types of signal lines providing electrical signals, pads are disposed. The non-display region NDA of the display module DM may correspond to the above-described bezel region BA. Components of the display module DM disposed on the non-display region NDA may be prevented from being viewed to the outside by the bezel region BA.

The light-shielding layer SL may be disposed below display module DM. The light-shielding layer SL may be directly disposed below the display module DM. The light-shielding layer SL may absorb at least some light among light incident from the outside of the electronic apparatus EE to the display module DM. For the light provided from the outside of the electronic apparatus EE, at least some light is absorbed in the light-shielding layer SL, and thus light reflected on the electronic apparatus EE and emitted to the outside may be minimized.

The housing HAU may be disposed below the display module DM to accommodate the display module DM and the light-shielding layer SL. The housing HAU may absorb impact applied from the outside, and may prevent foreign substances/moisture and the like from infiltrating the display module DM to thereby protect the display module DM. The housing HAU according to an embodiment may be provided in a form where multiple housing members are combined.

A display device according to an embodiment may be applied to various electronic devices. An electronic device according to an embodiment may include the foregoing display device, and further include a module or device having other additional function in addition to the display device.

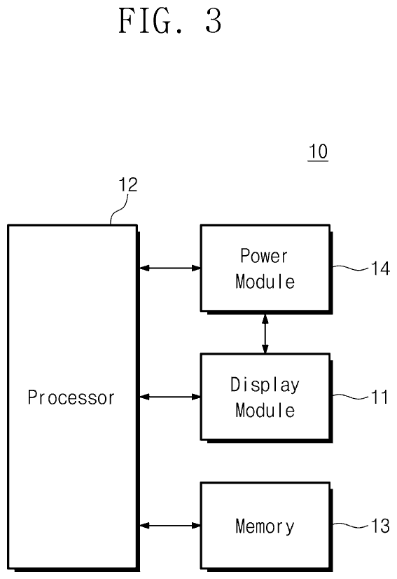

FIG. 3 is a block diagram of an electronic device according to an embodiment. Referring to FIG. 3, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for an operation of the processor 12 or the display module 11. When the processor 12 executes an application stored in the memory 13, an image data signal and/or an input control signal may be transmitted to the display module 11, and the display module 11 may process the provided signal and output image information through a display screen.

The power module 14 may include a power supply module such as a power adapter or a battery device, and a power conversion module which converts power supplied by the power supply module and generates power required for an operation of the electronic device 10.

At least one of the components of the electronic device 10 described above may be included in the display device according to an embodiment described above. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device 10.

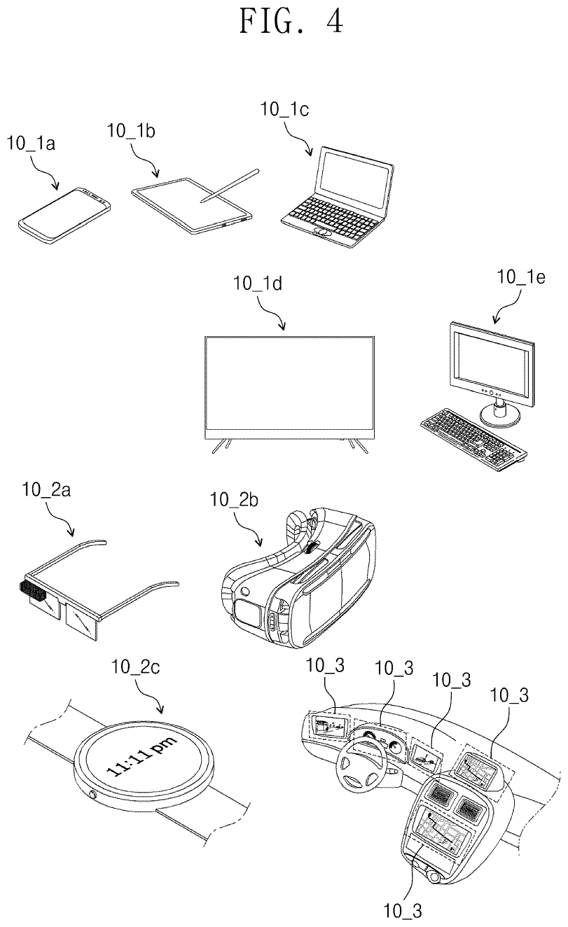

FIG. 4 illustrates schematic views of electronic devices according to various embodiments.

Referring to FIG. 4, various electronic devices to which the display device according to an embodiment is applied may include not only electronic devices for displaying images, e.g., a smartphone 10_1a, a tablet computer (PC) 10_1b, a laptop computer 10_1c, TV 10_1d, and a monitor for a desk computer 10_1e, but also wearable electronic devices including display modules, e.g., smart glasses 10_2a, a head mounted display 10_2b, and a smart watch 10_2c, and vehicle electronic devices 10_3 including display modules, e.g., a vehicle instrument panel, a center fascia, a center information display (CID) disposed on a dashboard, and a room mirror display.

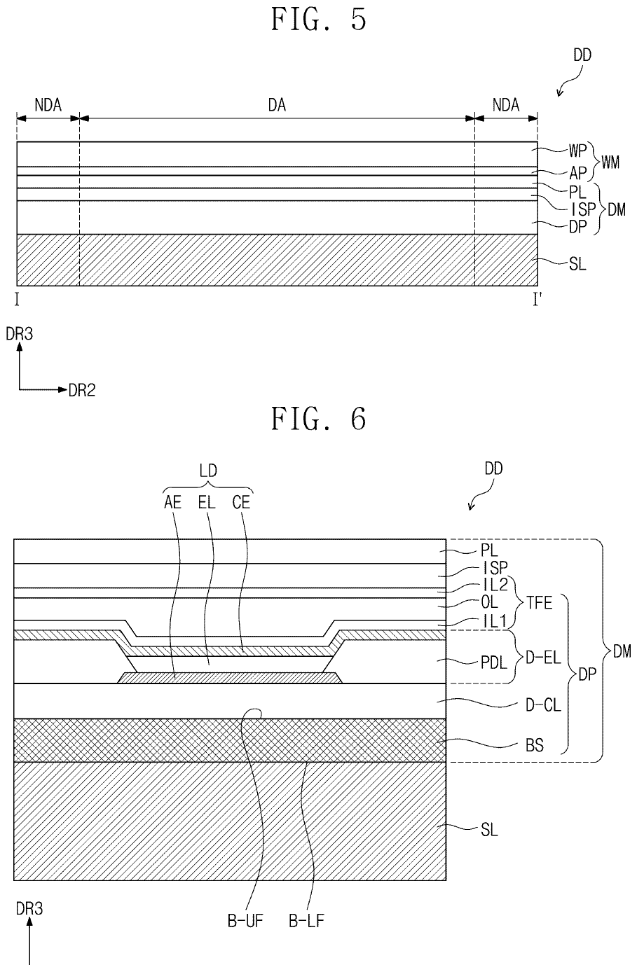

FIG. 5 is a cross-sectional view of a display module DD according to an embodiment of the inventive concept. FIG. 6 is an enlarged cross-sectional view illustrating a portion of the display device DD according to an embodiment of the inventive concept. In FIG. 6, some components of the display device DD are omitted, and a configuration of the display module DM and the light-shielding layer SL is illustrated in more detail. In FIG. 6, one light-emitting element disposed in the display region DA (see FIG. 2) and a peripheral region thereof are exemplified, and FIG. 6 and the contents explained with reference to FIG. 6 may similarly applied to the other light-emitting elements disposed in the display region DA (see FIG. 2) and the peripheral regions thereof.

Referring to FIG. 5 and FIG. 6, the display device DD according to an embodiment may include a display module DM, a window WM disposed on the display module DM, and a light-shielding layer SL disposed below the display module DM. The display module DM according to an embodiment may include a display panel DP and an input sensor ISP disposed on the display panel DP. In addition, the display module DM according to an embodiment may further include an optical layer PL disposed on the input sensor ISP.

In the display device DD according to an embodiment, the display panel DP may be a component substantially generating an image. The display panel DP may be a luminous-type display panel, and for example, the display panel DP may be an organic light-emitting display panel, an inorganic light-emitting display panel, a quantum dot display panel, a micro-LED display panel, a nano-LED display panel. The display panel DP may be referred to as a display layer.

Referring to FIG. 5 and FIG. 6, the display module DM may further include an optical layer PL disposed on the display panel DP. The optical layer PL may be disposed on the input sensor ISP. The optical layer PL may be a reflection reduction layer reducing reflectance caused by external light incident from the outside. The optical layer PL may be formed on the input sensor ISP through a continuous process. In an embodiment, the optical layer PL may include a polarizing layer.

For example, the optical layer PL may include a polarizing layer including a phase retarder and/or a polarizer, a multi-layered reflection layers that interfere destructively with reflected light, or color filters that are located corresponding to a pixel arrangement and emission colors of the display panel DP. For example, when the optical layer PL includes color filters, the color filters may be arranged in consideration of emission colors of the pixels included in the display panel DP. In addition, in an embodiment, the optical layer PL may be omitted.

The display device DD according to an embodiment may include a light-shield layer SL disposed below the display module DM. The light-shield layer SL may be directly disposed below the display module DM. The light-shield layer SL may absorb at least some light among incident light from the outside to the display module DM. For the light provided from the outside of the display device DD, since at least some light is absorbed in the light-shielding layer SL, the light reflected and emitted from the display device DD to the outside may be minimized.

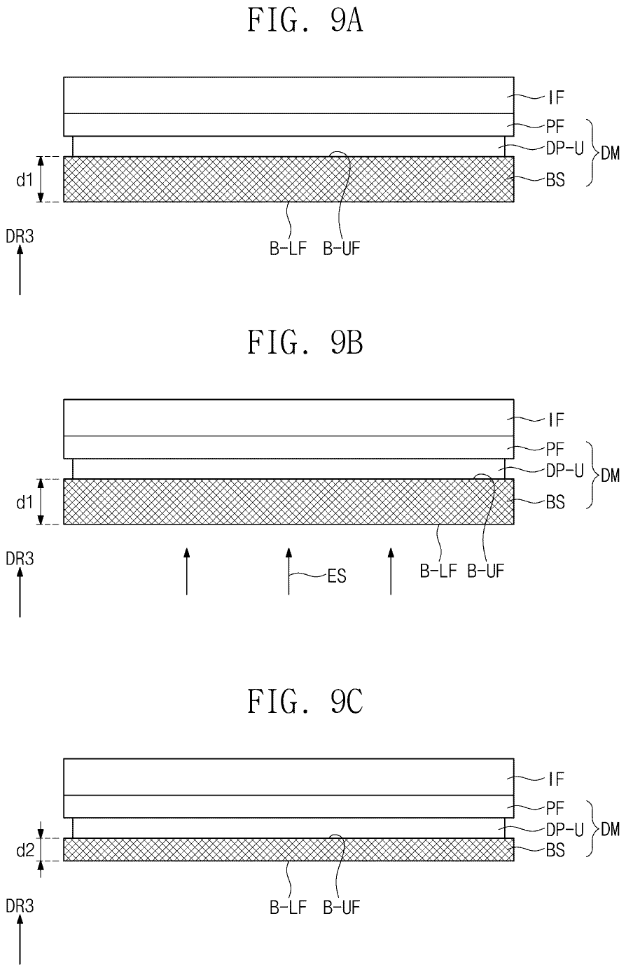

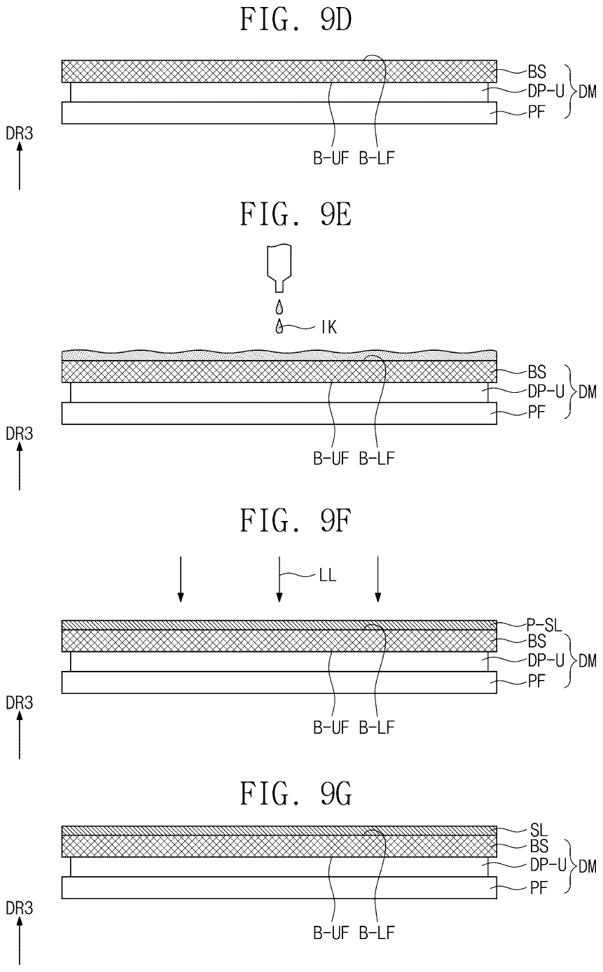

Although not illustrated, the display device DD according to an embodiment may further include a panel protecting film PF (see FIG. 9G) disposed on the display module DM. The panel protecting film PF (see FIG. 9G) may be disposed between the display module DM and the window WM. The panel protecting film PF (see FIG. 9G) may be a layer disposed on the display module DM protecting a top surface of the display module DM. The panel protecting film PF (see FIG. 9G) may overlap the entire display module DM. However, an embodiment of the inventive concept is not limited thereto, and the panel protecting film PF (see FIG. 9G) may be omitted in the display device DD according to an embodiment.

Referring to FIG. 6, the display module DM may include a display panel DP, an input sensor ISP, and an optical layer PL. The display panel DP according to an embodiment may include a base layer BS, a circuit layer D-CL, a display element layer D-EL, and an encapsulation layer TFE. In an embodiment, the light-shielding layer SL may be disposed below the base layer BS. The light-shielding layer SL maty be directly disposed below the base layer BS. The light-shielding layer SL may be in contact with a bottom surface of the base layer BS.

The base layer BS may be a member providing a base surface on which a circuit layer D-CL is disposed. The base layer BS may be a rigid substrate, or a flexible substrate that is bendable, foldable, rollable, and the like. The base layer BS may be a glass substrate, a metal substrate, a polymer substrate, or the like. However, an embodiment of the inventive concept is not limited thereto, and the base layer BS may be an inorganic layer, an organic layer, or a composite material layer. In an embodiment, the base layer BS may be a glass substrate.

Referring to FIG. 6, the base layer BS may include a top surface B-UF and a bottom surface B-LF, which are opposite with respect to the third direction DR3, which is a thickness direction. The top surface B-UF of the base layer BS may be a surface adjacent to the display element layer D-EL, and the bottom surface B-LF of the base layer BS may be a surface opposite to the top surface B-UF and spaced apart from the display element layer D-EL. The bottom surface B-LF of the base layer BS may be a surface adjacent to the light-shielding layer SL. The bottom surface B-LF of the base layer BS may be in contact with the light-shielding layer SL.

The circuit layer D-CL may be disposed on the base layer BS. The circuit layer D-CL may include a plurality of insulating layers, a plurality of transistors, a conductive pattern, signal lines, etc. In an embodiment, a plurality of inorganic films, a plurality of organic films, a semiconductor layer, and a conductive layer may be formed by using a method such as coating, and deposition. Thereafter, the inorganic films, the organic films, the semiconductor layer, and the conductive layer may be selectively patterned by a photolithography method. Using such a method, the circuit layer D-CL including a plurality of insulating layers respectively formed from the inorganic films and the organic films, transistors including a semiconductor pattern formed from the semiconductor layer, and the conductive pattern formed from the conductive layer, and signal lines may be formed. In FIG. 6, the configuration of the circuit layer D-CL is briefly illustrated, and transistors and signal lines of the circuit layer D-CL may be electrically connected to the light-emitting element LD of the display element layer D-EL.

Thereafter, the display element layer D-EL may be formed on the circuit layer D-CL, and an encapsulation layer TFE covering the display element layer D-EL may be formed.

The display element layer D-EL may include a pixel definition film PDL and a light-emitting element LD. The light-emitting element LD may include a first electrode AE, an emission layer EL, and a second electrode CE.

The first electrode AE may be referred to as a pixel electrode. The first electrode AE may be formed using a metal material, a metal alloy or a conductive compound. The first electrode AE may be an anode or cathode. The first electrode AE may be a transmissive electrode, a transflective electrode, or a reflective electrode. When the first electrode AE is a transmissive electrode, the first electrode AE may include a transparent metal oxide such as indium tin oxide (ITO), indium zinc oxide (IZO), zinc oxide (ZnO), and indium tin zinc oxide (ITZO). When the first electrode AE is a transflective electrode or a reflective electrode, the first electrode AE may include Ag, Mg, Cu, Al, Pt, Pd, Au, Ni, Nd, Ir, Cr, Li, Ca, LiF/Ca, LiF/Al, Mo, Ti, or W, or a compound or a mixture thereof (e.g., a mixture of Ag and Mg). Alternatively, the first electrode AE may have a multi-layered structure including a reflective film, or a transflective film formed using the above-described material, and a transparent conductive film formed using indium tin oxide (ITO), indium zinc oxide (IZO), zinc oxide (ZnO), and indium tin zinc oxide (ITZO). For example, the first electrode AE may have a three-layered structure of ITO/Ag/ITO, but is not limited thereto. In addition, an embodiment of the inventive concept is not limited thereto, and the first electrode AE may include the above-described metal material, a combination of two metal materials selected from the above-described metal materials, an oxide of the above-described metal material, etc.

The pixel definition film PDL may be disposed on the circuit layer D-CL. In an embodiment, the pixel definition film PDL may be formed using a polymer resin. For example, the pixel definition film PDL may be formed using a polyacrylate-based resin, or a polyimide-based resin. In addition, the pixel definition film PDL may be formed by further including an inorganic material in addition to the polymer resin. The pixel definition film PDL may be formed including light-absorbing material, or may be formed including a black pigment or a black dye. The pixel definition film PDL formed including the black pigment or the black dye may implement a black pixel definition film. During the formation of the pixel definition film PDL, as the black pigment or the black dye, carbon black and the like may be used, but an embodiment of the inventive concept is not limited thereto.

In addition, the pixel definition film PDL may be formed using an inorganic material. For example, the pixel definition film PDL may be formed including silicon nitride, silicon oxide, silicon oxynitride, or the like.

In the pixel definition film PDL, a pixel opening part which exposes a portion of the first electrode AE may be defined. In the display module DM according to an embodiment, emission regions may be distinguished by the pixel definition film PDL. In the display module DM, the emission region may be defined as a portion which is exposed without overlapping the pixel definition film PDL, and overlaps the emission layer EL.

In the light-emitting element LD, the emission layer EL may be disposed on the first electrode AE. In the present embodiment, the emission layer EL may emit light in at least one color among blue, red, and green. Unlike this, in an embodiment, the emission layer EL may provide blue light throughout the entire display region DA (see FIG. 2). In this case, the display module DM may further include the configuration of an optical control unit that converts the wavelength of light emitted from the light-emitting element LD.

The second electrode CE may be disposed on the emission layer EL. The second electrode CE may have an integrated shape and may be commonly disposed on multiple light-emitting elements disposed in the display region DA (see FIG. 2). The second electrode CE may be referred to as a common electrode. The second electrode CE may be a cathode or an anode. For example, if the first electrode AE is an anode, the second electrode CE may be a cathode, and if the first electrode AE is a cathode, the second electrode CE may be an anode.

The second electrode CE may be a transmissive electrode, a transflective electrode, or a reflective electrode. When the second electrode CE is a transmissive electrode, the second electrode CD may be formed by using a transparent metal oxide such as indium tin oxide (ITO), indium zinc oxide (IZO), zinc oxide (ZnO), or indium tin zinc oxide (ITZO). In addition, the second electrode CE may be formed including Ag, Mg, Cu, Al, Pt, Pd, Au, Ni, Nd, Ir, Cr, Li, Ca, LiF/Ca, LiF/Al, Mo, Ti, or W, or a compound or a mixture thereof (e.g., a mixture of Ag and Mg).

Although not illustrated, a hole control layer may be disposed between the first electrode AE and the emission layer EL. The hole control layer may include a hole transport layer, and may further include a hole injection layer. An electron control layer may be further included between the emission layer EL and the second electrode CE. The electron control layer may include an electron transport layer, and may further include an electron injection layer. The hole control layer and the electron control layer may be commonly formed in a plurality of light-emitting elements using an open mask in the entire display region DA (see FIG. 2).

The encapsulation layer TFE may be disposed on the display element layer D-EL. The encapsulation layer TFE may include a first inorganic layer IL1, an organic layer OL, and a second inorganic layer IL2, which are sequentially stacked. However, layers constituting the encapsulation layer TFE are not limited thereto.

The inorganic layers IL1 and IL2 may protect the display element layer D-EL from moisture and oxygen, and the organic layer OL may protect the display element layer D-EL from foreign substances such as dust particles. The inorganic layers IL1 and IL2 may include at least one among silicon nitride, silicon oxynitride, silicon oxide, titanium oxide, or aluminum oxide. The organic layer OL may include an acryl-based organic material. However, materials constituting the inorganic layers IL1 and IL2 and the organic layer OL are not limited thereto.

The input sensor ISP may be disposed on the encapsulation layer TFE. In an embodiment, the input sensor ISP may include insulating layers and a sensor conductive layer. In an embodiment, the input sensor ISP may be directly disposed on the encapsulation layer TFE.

The display module DM according to an embodiment may include an optical layer PL. In an embodiment, the optical layer PL may be directly disposed on the input sensor ISP. However, an embodiment of the inventive concept is not limited thereto, and an adhesion layer and the like may be further included between the optical layer PL and the input sensor ISP. The optical layer PL may be a reflection reduction layer that reduces the external light. In an embodiment, the optical layer PL may be omitted.

In an embodiment, the light-shielding layer SL may be an optical member disposed below the display module DM and absorbing light incident through the display module DM, and may function as a support member supporting the display module DM.

In an embodiment, the light-shielding layer SL may be formed using the ink composition according to an embodiment to be described later. The light-shielding layer SL may be directly provided on the bottom surface B-LF of the base layer BS to be in contact with the bottom surface B-LF of the base layer BS. The light-shielding layer SL may include a material for light shielding. For example, the light-shielding layer SL may include a pigment such as carbon black as a light-shielding material. The light-shielding layer SL includes a predetermined color, and thus may be a layer having a color.

The light-shielding layer SL may have a thickness of about 9 μm to about 16 μm. For example, the thickness of the light-shielding layer SL may be about 12 μm. When the thickness of the light-shielding layer SL falls within the above-described range, excellent light-shielding properties may be shown, and the functional layers disposed above the display module DM may be protected due to the sufficient thickness, thereby exhibiting excellent durability and reliability properties.

The light-shielding layer SL may be a single layer formed through a single process. That is, the light-shielding layer SL may be formed as a single layer in an integrated shape, without including multiple layers separated by interfaces. However, an embodiment of the inventive concept is not limited thereto, and the light-shielding layer SL may include multi layers.

In an embodiment, the light-shielding layer SL may be directly disposed below the base layer BS. The light-shielding layer SL may be directly disposed on the base layer BS without an additional adhesion member. The ink composition according to an embodiment to be described later may be provided below the display module DM and then the coated ink composition may be photo-cured to form the light-shielding layer SL. In an embodiment, the ink composition according to an embodiment may be provided below the display module DM by a screen-printing method, and then the provided ink composition may be photo-cured to form the light-shielding layer SL.

Hereinafter, the ink composition according to an embodiment of the inventive concept will be described.

The ink composition according to an embodiment of the inventive concept may be used for forming the light-shielding layer included in the electronic apparatus. The ink composition according to an embodiment of the inventive concept may be used for forming the light-shielding layer disposed on the rear surface of the display module. More specifically, the ink composition according to an embodiment may be applied on the rear surface of the display module and then photo-cured to form the light-shieling layer.

The ink composition according to an embodiment of the inventive concept includes a base resin, a photo initiator, and a mill base. In addition, the ink composition according to an embodiment, in addition to the base resin, the photo initiator, and the mill base, may further include an additive including at least one among a photopolymerizable monomer, a coupling agent, an antistatic agent, a leveling agent, and a defoamer. In addition, the ink composition according to an embodiment may include no solvent.

In the ink composition of the present disclosure, the base resin may serve in adjusting a crosslinking density of the entire coating layer, thereby expressing strength, durability, and surface hardness of the coating layer when the ink composition is cured, and improving adhesion to the other materials. As the base resin, any conventional component known in the art may be used without limitation. For example, the base resin may be a (meth)acrylic resin, an imide-based resin, an epoxy-based resin, a urethane-based resin, or a siloxane-based resin. The base resin may be a polymer having a weight average molecular weight of about 5000 to about 50000.

In an embodiment, the base resin may include at least one among a (meth)acrylate-based resin and an imide-based resin.

The (meth)acrylate-based resin may mean a polymer compound derived from a monomer including an acrylate or methacrylate functional group within a molecular structure. The (meth)acrylate-based resin may include, for example, at least one among alkyl (meth)acrylate, hydroxy alkyl acrylate, polyethylene glycol alkyl ether methacrylate, perfluoroalkyl (meth)acrylate and silicone (meth)acrylate. The imide-based resin may mean a polymer compound including an imide-linkage within a molecular structure. The imide-based resin contains an imide-linkage, and thus may have excellent heat resistance, chemical resistance, and abrasion resistance.

The base resin may be included in an amount of about 25 wt % to about 60 wt % with respect to the total amount 100% of the ink composition. When the base resin is included in the above-described amount range, excellent coating property, adhesion, and the like may be obtained.

The photo initiator may serve to initiate photopolymerization when excited by ultraviolet light and the like in the ink composition according to an embodiment of the inventive concept. The photo initiator may have a maximum absorbance in the wavelength range of about 305 nm to about 405 nm. As the photo initiator, any conventional initiator commonly used in the art may be used without limitation. For example, the photo initiator may include at least one among an acetophenone-based compound, a benzophenone-based compound, a thioxanthone-based compound, a benzoin-based compound, an oxime ester-based compound, and a triazine-based compound.

Examples of the acetophenone-based compound may include, for example, 2,2′-diethoxy acetophenone, 2,2′-dibutoxy acetophenone, 2-hydroxy-2-methyl propiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)butan-1-one, etc.

Examples of the benzophenone-based compound may include, for example, benzophenone, benzoyl benzoic acid, benzoyl benzoic acid methyl, 4-phenyl benzophenone, hydroxy benzophenone, acrylated benzophenone, 4,4′-bis(dimethylamino)benzophenone, 4,4′-bis(diethylamino)benzophenone, 4,4′-dimethylamino benzophenone, 4,4′-dichlorobenzophenone, 3,3′-dimethyl-2-methoxybenzophenone, etc.

Examples of the thioxanthone-based compound may include, for example, thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include, for example, benzoin, benzoin methyl ether, benzoin ethyl ether, benzoin isopropyl ether, benzoin isobutyl ether, benzyl dimethyl ketal, etc.

Examples of the oxime ester-based compound may include, for example, o-ethoxycarbonyl-α-oxyimino-1-phenylpropane-1-one, etc., and OXE-01, OXE-02, and the like made by BASF, as commercial products, may be included.

Examples of the triazine-based compound may include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl-4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxynaphtho-1-yl)-4,6-bis(trichloromethyl)-s-triazine, 2,4-trichloromethyl(piperonyl)-6-triazine, 2,4-trichloromethyl(4′-methoxystyryl)-6-triazine, etc.

The photo initiator may include, in addition to the above-described compounds, a carbazole-based compound, a diketone-based compound, a sulfonium borate-based compound, a diazo-based compound, an imidazole-based compound, a non-imidazole-based compound, etc.

The photo initiator may be included in an amount of about 5 wt % to about 15 wt %, with respect to the total amount 100% of the ink composition. When the photo initiator is included in the ink composition in the above-described range, sufficient curing occurs during the exposure, which may improve reliability of the coating layer. In addition, excellent durability and adhesion of the formed coating layer may be provided, and defects caused by an unreacted monomer may be prevented.

In the ink composition according to an embodiment of the inventive concept, the mill base includes a pigment, a dispersant, and a (meth)acrylate monomer. In the ink composition according to an embodiment, the mill base may be included in an among about 5 wt % to about 20 wt %, with respect to the total amount 100 wt % of the ink composition.

In an embodiment, the pigment may be an organic pigment and/or an inorganic pigment.

As a pigment, a black pigment and the like may be used. The black pigment may include: an inorganic black pigment such as carbon black; an organic black pigment such as lactam black, aniline black, and a perylene-based black pigment; and the like.

The pigment may be used alone or a mixture of two or more thereof may be used. The pigment according to an embodiment may include a black pigment, and a mixture of two or more colored pigments. For example, as a pigment in the ink composition according to an embodiment, a black pigment may be used alone, or a mixture of two or more colored pigments, such as red, green, blue, yellow, and/or black pigments, may be used but is not limited thereto.

The light-shielding layer formed from the ink composition according to an embodiment may have a black color. In an embodiment, the light-shielding layer may be formed from the ink composition including a black pigment. For example, the light-shielding layer may be formed from the ink composition including carbon black. Therefore, the light-shielding layer may absorb reflected light due to the external light, and thus may improve display quality of the display device.

The dispersant may serve to uniformly disperse a pigment such as carbon black within the ink. The dispersant may adsorb onto a surface of the pigment and may include a functional group that has an affinity for the pigment.

In an embodiment, the dispersant may have at least one of an amine value, or an acid value. For example, the dispersant may have any one among an amine value or an acid value, or may have both an amine value and an acid value at the same time. When the dispersant has an amine value, the amine value may be in a range of about 1 mg KOH/g to about 120 mg KOH/g. When the dispersant has an acid value, the acid value may be in a range of about 1 mg KOH/g to about 120 mg KOH/g. However, an embodiment of the inventive concept is not limited thereto.

As the dispersant, a non-ionic dispersant, an anionic dispersant, a cationic dispersant, and the like may be used, but an embodiment of the inventive concept is not limited thereto. Specific examples of the dispersant may include polyalkylene glycol and esters thereof, polyoxyalkylene, polyol ester alkylene oxide adducts, alcohol alkylene oxide adducts, sulfonic acid esters, sulfonic acid salts, carboxylic acid esters, carboxylic acid salts, alkylamide alkylene oxide adducts, alkylamine, etc., which may be used alone or in combination of two or more.

The (meth)acrylate monomer contained in a mill base according to an embodiment includes two monomers having different viscosities. In an embodiment, (meth)acrylate includes a first monomer having a first viscosity and a second monomer having a second viscosity greater than the first viscosity. The first monomer may be a (meth)acrylate monomer having a relatively low viscosity and the second monomer may be a (meth)acrylate monomer having a relatively high viscosity.

The first monomer may have the first viscosity of about 1 cP to about 50 cP at about 25° C. For example, the first viscosity may be about 2 cP to about 20 cP. The first monomer may be added for improving dispersibility and storage stability in addition to for surface modification of the pigment. By milling the first monomer having relatively low viscosity properties with a pigment and a dispersant, excellent surface modification properties, dispersibility, and storage stability may be achieved even without the use of an additional solvent.

The second monomer may have a second viscosity of about 100 cP to about 10000 cP at about 25° C. For example, the second viscosity may be about 100 cP to about 5000 cP. The second monomer may be included in the mill base to thereby increase compatibility with various base resins. The second monomer has a relatively higher viscosity than the first monomer, which may increase an entire viscosity of the mill base. The second monomer may be added after a milling process to be described later. Since the second monomer is mixed in the mill base, compatibility with the base resin within the ink composition may increase, and thus material stability and processibility of the ink composition may be further improved.

In an embodiment, a difference between the first viscosity of the first monomer and the second viscosity of the second monomer may be about 100 cP to about 5000 cP. For example, a difference between the first viscosity and the second viscosity may be about 1000 cP to about 5000 cP.

As the first monomer and the second monomer, a known (meth)acrylate monomer containing one or more (meth)acrylate groups within a molecule may be used without limitation.

Generally, the (meth)acrylate monomer may be classified into monofunctional (meth)acrylate monomers (1), difunctional (meth)acrylate monomers (2), and multifunctional (meth)acrylate monomers (3 or more) depending on the number of (meth)acrylate groups included in one molecule.

In the ink composition of the inventive concept, the first monomer and the second monomer may be selected from the above-described monofunctional, difunctional, multifunctional (meth)acrylate monomers and used depending on viscosity. (Meth)acrylate monomers that fall within in the above-described first and second viscosity ranges may be appropriately selected and respectively used as the first and second monomers.

Examples of the monofunctional (meth) acrylate monomers may be, for example, methyl(meth)acrylate, ethyl(meth)acrylate, propyl(meth)acrylate, n-butyl(meth)acrylate, isobutyl(meth)acrylate, tert-butyl(meth)acrylate, 2-ethylhexyl(meth)acrylate, isodecyl(meth)acrylate, isoamyl(meth)acrylate, isomyristyl(meth)acrylate, n-lauryl(meth)acrylate, n-stearyl(meth)acrylate, isostearyl(meth)acrylate, long-chain alkyl(meth)acrylate, n-butoxyethyl(meth)acrylate, butoxy diethylene glycol(meth)acrylate, cyclohexyl(meth)acrylate, tetrahydrofurfuryl(meth)acrylate, butoxyethyl(meth)acrylate, 2-ethylhexyl-diglycol(meth)acrylate, dicyclopentenyl(meth)acrylate, dicyclopentenyl oxyethyl(meth)acrylate, dicyclopentanyl(meth)acrylate, benzyl(meth)acrylate, 2-hydroxyethyl(meth)acrylate, 2-hydroxypropyl(meth)acrylate, 2-hydroxybutyl(meth)acrylate, 2-(2-vinyloxyethoxy)ethyl(meth)acrylate, glycidyl(meth)acrylate, methoxyethylene glycol-modified(meth)acrylate, ethoxyethylene glycol-modified(meth)acrylate, propoxyethylene glycol-modified(meth)acrylate, methoxypropylene glycol-modified(meth)acrylate, ethoxypropylene glycol-modified(meth)acrylate, propoxypropylene glycol-modified(meth)acrylate, tetrahydrofuryl(meth)acrylate, acryloyl morpholine, etc.

In addition, examples of the monofunctional (meth)acrylate having an aromatic ring may be phenoxymethyl(meth)acrylate, phenoxyethyl(meth)acrylate, phenoxyethylene glycol-modified (meth)acrylate, phenoxypropylene glycol-modified (meth)acrylate, hydroxyphenoxyethyl(meth)acrylate, 2-hydroxy-3-phenoxypropyl(meth)acrylate, hydroxyphenoxyethylene glycol-modified (meth)acrylate, hydroxyphenoxypropylene glycol-modified (meth)acrylate, alkylphenol ethylene glycol-modified (meth)acrylate, alkylphenol propylene glycol-modified (meth)acrylate, ethoxylated o-phenylphenol(meth)acrylate, isobornyl(meth)acrylate, etc.

Examples of the difunctional (meth)acrylate monomer may be, for example, ethylene glycol di(meth)acrylate, propylene glycol di(meth)acrylate, tripropylene glycol di(meth)acrylate, polyolefin glycol di(meth)acrylate, polyethylene glycol di(meth)acrylate, ethoxylated polypropylene glycol di(meth)acrylate, 2-hydroxy-1,3-dimethacryloxypropane, dioxane glycol di(meth)acrylate, tricyclodecane dimethanol di(meth)acrylate, 1,4-butanediol di(meth)acrylate, glycerin di(meth)acrylate, 1,6-hexanediol di(meth)acrylate, 1,9-nonanediol di(meth)acrylate, 1,10-decanediol di(meth)acrylate, neopentyl glycol di(meth)acrylate, 2-methyl-1,8-octanediol di(meth)acrylate, 1,9-nonanediol di(meth)acrylate, butylethylpropanediol di(meth)acrylate, 3-methyl-1,5-pentanediol di(meth)acrylate, etc.

In addition, examples of the difunctional (meth)acrylate monomer having an aromatic ring may include ethoxylated bisphenol A di(meth)acrylate, propoxylated ethoxylated bisphenol A di(meth)acrylate, ethoxylated bisphenol F di(meth)acrylate, etc.

Examples of the multifunctional (meth)acrylate may include, for example, ethoxylated glycerin tri(meth)acrylate, trimethylolpropane tri(meth)acrylate, ethoxylated trimethylolpropane tri(meth)acrylate, propoxylated trimethylolpropane tri(meth)acrylate, pentaerythritol tri(meth)acrylate (tri-functional monomers); pentaerythritol tetra(meth)acrylate, ditrimethylolpropane tetra(meth)acrylate, ethoxylated pentaerythritol tetra(meth)acrylate (tetra-functional monomers); dipentaerythritol hexa(meth)acrylate (penta-functional monomers), dipentaerythritol polyacrylate, etc.

In an embodiment, the first monomer may include 1,6-hexanediol Diacrylate (HDDA), tetrahydrofurfuryl acrylate (THFA), isobornyl acrylate (IBOA), 2-hydroxyethyl methacrylate (2-HEMA), tripropylene glycol diacrylate (TPGDA), and trimethylolpropane triacrylate (TMPTA), and the second monomer may include pentaerythritol triacrylate (PETTA), dipentaerythritol pentaacrylate (DPPA), and dipenta erythritol hexaacrylate (DPHA).

The mill base included in the ink composition according to an embodiment of the inventive concept includes a (meth)acrylate monomer having a low viscosity and a (meth)acrylate monomer having a high viscosity. As the mill base according to an embodiment, a mixture of the (meth)acrylate monomer having a low viscosity and the (meth)acrylate monomer having a high viscosity is used, and dispersibility, storage stability, processibility, and the like of the ink composition may be improved by appropriately arranging the mixing order of the pigment and the monomers. The ink composition according to an embodiment may exhibit excellent dispersibility, storage stability and processibility without including additional solvent.

In the ink composition according to an embodiment, with respect to the total amount 100 wt % of the mill base, the mill base may include about 5 wt % to about 30 wt % of the pigment, about 2 wt % to about 10 wt % of the dispersant, about 30 wt % to about 45 wt % of the first monomer, and about 30 wt % to about 45 wt % of the second monomer. Since, in the ink composition according to an embodiment, the amounts of the pigment, the dispersant, the first monomer, and the second monomer included in the mill base fall within the above-described ranges, excellent storage stability, and dispersion stability may be exhibited.

The ink composition according to an embodiment may further include an additive including at least one among a photopolymerizable monomer, a coupling agent, and an antistatic agent, a leveling agent, and a defoamer in addition to the base resin, the photo initiator, and the mill base.

The photo polymerizable monomer may be used as a reactive diluent for a photoreactive polymer, may impart processibility by adjusting a viscosity of the ink composition and may function as a cross-linker for adjusting crosslink density between polymers. For a coating layer formed using the ink composition according to an embodiment of the inventive concept, the photo polymerizable monomer is included for aiding curing properties of the coating layer such as hardness, adhesion and hardness.

The photo polymerizable monomer may be a monomer including two or more polymerizable groups. The photo polymerizable groups may be a (meth)acrylate group, a carbon-carbon double bond such as a vinyl group, an epoxy group, etc. The photo polymerizable monomer according to an embodiment may include 2 to 16 polymerizable groups.

In an embodiment, the photo polymerizable monomer may be a (meth)acrylate monomer. As the (meth)acrylate monomer, a known (meth)acrylate monomer, which contains two or more (meth)acrylate groups within a molecule may be used without limitation.

In an embodiment, the photo polymerizable monomer has two or more polymerizable functional groups such as a (meth)acrylate group in one molecule, and may include difunctional acryl monomers (containing 2 polymerizable functional groups) or multifunctional acryl monomers (containing 3 or more polymerizable functional groups).

In the ink composition according to the inventive concept, the above-described difunctional, or multifunctional (meth)acrylate monomer may be used separately, or the difunctional and multifunctional (meth)acrylate monomers may be used in a combination.

In the ink composition according to an embodiment, the same monomer as the second monomer included in the mill base may be used as the photo polymerizable monomer. Since the same monomer as the second monomer is used as the photo polymerizable monomer, compatibility of the mill base within the ink composition may increase. However, an embodiment of the inventive concept is not limited thereto, and the photo polymerizable monomer may be different from the second monomer.

In an embodiment, the photo polymerizable monomer may be included in an amount of about 25 wt % to about 60 wt %, with respect to the total amount 100 wt % of the ink composition. Since the amount of the photo polymerizable monomer falls within the above-described range, viscosity and crosslink density of the ink composition may be appropriately adjusted to thereby improve adhesion and processibility of the cured coating layer.

The coupling agent may include at least one among a silane-based compound and a siloxane-based compound. The silane-based compound may serve to impart adhesion to the coating layer formed using a photo-curable resin composition, and the siloxane-based compound may serve as a wetting agent imparting wetting to the coating layer formed using the photo-curable resin composition. The coupling agent may be included in an amount of about 0.5 wt % to about 3 wt % with respect to the total amount 100 wt % of the ink composition.

The antistatic agent may serve to prevent static electricity by lowering a surface electrical resistance of the coating layer formed using the ink composition. As the antistatic agent, a known material in the art may be used without limitation. In an embodiment, the coating layer formed using the ink composition including the antistatic agent may have a surface resistance value of about 10¹⁰Ω/□ or less.

The leveling agent may be included for purposes of further increasing adhesion in the ink composition by leveling to ensure flat and smooth coating when applying the ink composition. As the leveling agent, an acryl-based leveling agent, a silicon-based leveling agent, and the like may be used alone or as a mixture of two or more. For example, polyether-modified polydimethylsiloxane may be included, and a (meth)acryloyl group may be added within the polyether chain.

The defoamer is a mixture of oleophilic material and polysiloxane, and may serve to increase appearance properties of the coating layer by destroying bubbles generated during the coating.

In an embodiment, the additive may be included in an amount of about 0.2 wt % to about 4 wt %, with respect to the total amount 100 wt % of the ink composition.

In the ink composition according to the inventive concept, a known functional additive in the art may be further included within a range that does not impair the effects of the inventive concept. Examples of the usable functional additives may include, for example, an antioxidant, a lubricant, a surfactant, an adhesion promoter, a slip agent, a solvent, a wetting agent, a light stabilizer, a stain inhibitor, a plasticizer, a thickener, a polymer, etc. These may be used alone, or a mixture of two or more may be used.

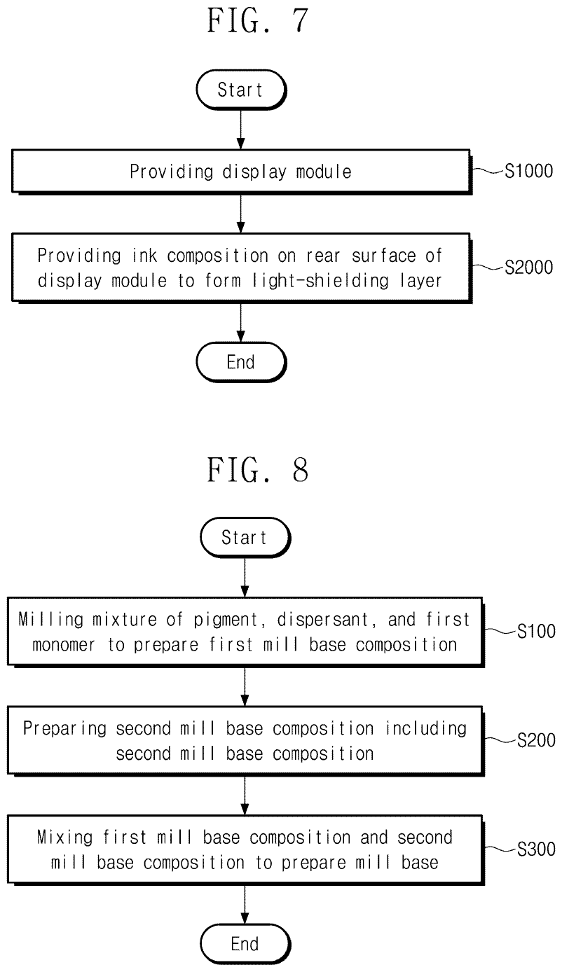

FIG. 7 is a flow chart showing a method of manufacturing an electronic apparatus according to an embodiment of the inventive concept. FIG. 8 is a flow chart showing some processes for the preparation of the ink composition according to an embodiment of the inventive concept. FIG. 8 is a flow chart showing in detail preparing the mill base among the preparation of the ink composition according to the inventive concept.

Referring to FIG. 7, the method of manufacturing the electronic apparatus according to an embodiment includes preparing a display module S1000; and providing the ink composition on the rear surface of the display module to form a light-shielding layer (S2000).

The method of manufacturing an electronic apparatus according to an embodiment may further include preparing an ink composition. The light-shielding layer SL illustrated in FIG. 2 and the like may be formed through a process forming the light-shielding layer using the above-described ink composition.

In the method of manufacturing an electronic apparatus according to an embodiment, the preparation of the ink composition may include preparing a mill base. In an embodiment, the mill base may be formed by mixing a first mill base composition including a pigment, a dispersant and a first monomer, and a second mill base composition including a second monomer.

Referring to FIG. 8, the preparation of the mill base includes: preparing a first mill base composition (S100) by milling a mixture in which a pigment, a dispersant and a first monomer are mixed; preparing a second mill base composition (S200) including a second monomer; and mixing the first mill base composition and the second mill base composition to prepare a mill base (S300).

In an embodiment, preparing the first mill base composition (S100) and preparing the second mill base composition (S200) may be performed through an additional process. The first mill base composition and the second mill base composition may be provided separately, and then may be mixed with each other through the mixing process and provided in a mill base form.

In an embodiment, the preparation of the first mill base (S100) may include preparing a mixture in which a pigment, a dispersant, and a first monomer are mixed, and then milling the mixture. Through the milling process, the pigment may be milled into small particles and may be surface-modified by the dispersant. That is, through the milling process, the pigment may be milled in a small size and surface-modified by the dispersant at the same time. The dispersant may be adsorbed on surfaces of the milled particles. Accordingly, the milled pigment particles in a small size may be prevented from agglomerating and may be evenly distributed within the composition by the dispersant. In an embodiment, in a milling process, a ball mill method, a bead mill method, or the like may be used.

The first monomer included in the first mill base composition may be a monomer having a relatively low viscosity. The first monomer may have a first viscosity of about 1 cP to about 20 cP at about 25° C. For example, the first viscosity may be about 2 cP to about 15 cP. The first monomer may be added for improving dispersibility, and storage stability in addition to a surface-modification of the pigment. By milling the first monomer having the relatively low viscosity properties by mixing with the pigment and the dispersant, excellent surface-modification properties, dispersibility, and storage stability may be exhibited without using additional solvent.

The second monomer included in the second mill base composition may have higher viscosity than the first monomer included in the first mill base composition. The second monomer may have a second viscosity of about 100 cP to about 10000 cP at about 25° C. For example, the second viscosity may be about 100 cP to about 5000 cP. The second monomer may be included within the mill base to thereby increase compatibility with various base resins. The second monomer has a higher viscosity than the first monomer, which may increase a viscosity of the entire mill base. The second monomer may be added after a milling process to be described later. Since the second monomer is mixed in the mill base, compatibility with the base resin within the ink composition may increase, and thus material stability and processibility of the ink composition may be further improved.

Thereafter, preparing the mill base may be performed by mixing the first mill base composition and the second mill base composition. Within the first mil base composition, the pigment may be in a milled and surface-modified state through the milling process. Therefore, the dispersibility of the pigment may not be reduced even when the first mill base composition is mixed with the second mill base composition including the second monomer having a relatively high viscosity.

The mill base according to an embodiment is formed by mixing: the first mill base composition including the first monomer having a low viscosity, the pigment, and the dispersant; and the second mill base composition having a high viscosity, and the mixing orders of the pigment and the monomers may be appropriately arranged to thereby improve dispersibility, storage stability, processibility and the like of the ink composition. The ink composition according to an embodiment may exhibit excellent dispersibility, storage stability, and processibility without including additional solvent.

FIG. 9A to FIG. 9G are each a cross-sectional view showing some processes among a method of manufacturing an electronic apparatus according to an embodiment of the inventive concept. FIG. 9A to FIG. 9G sequentially show providing a light-shielding layer among a method of manufacturing an electronic apparatus according to an embodiment. For describing a method of manufacturing an electronic apparatus according to an embodiment, the explanation of the above-described light-shielding layer according to an embodiment may be applied to a light-shielding layer. Hereinafter, for describing the method of manufacturing an electronic apparatus according to an embodiment with reference to FIG. 9A to FIG. 9G, for the same components as the previously described components, the same reference numerals are assigned, and detailed descriptions are omitted.

Referring to FIG. 9A, the method of manufacturing an electronic apparatus according to an embodiment may include providing a display module DM. The descriptions for the display module DM explained in FIG. 2 and the like may be similarly applied to the display module DM, which is described with reference to FIG. 9A to FIG. 9G.

The display module DM may include a base layer BS, and an upper panel member DP-U disposed on the base layer BS. The upper panel member DP-U illustrated in FIG. 9A to FIG. 9G may indicate functional layers other than base layer BS among functional layers included in the display module DM illustrated in FIG. 6. That is, the upper panel member DP-U may include a circuit layer D-CL, a display element layer D-EL, an encapsulation layer TFE, an input sensor ISP, and an optical layer PL. However, constitutions of the upper panel member DP-U are not limited thereto, and at least one among the functional layers included in the upper panel member DP-U may be omitted as needed.

The display module DM may include a top surface and a bottom surface, which are opposite with respect to the third direction DR3 corresponding to a light emitting direction. The bottom surface of the display module DM may be defined by the bottom surface B-LF of the base layer BS.

The display module DM may further include a panel protecting film PF disposed on the upper panel member DP-U. The panel protecting film PF may protect the top surface of the display module DM, disposed on the display module DM. The panel display film PF may overlap the entire display module DM. The panel protecting film PF may include a polymer material. For example, the panel protecting film PF may be a polyimide film or polyethylene terephthalate film. However, this is suggested as an example, and a material of the panel protecting film PF is not limited thereto.

In the method of manufacturing an electronic apparatus according to an embodiment, the display module DM may be provided, on the top surface, in an attached state of an acid-resistant film IF. For example, as illustrated in FIG. 9A, on the top surface of the display module DM, the acid-resistant film IF may be attached. The acid-resistant film IF may be attached on the panel protecting film PF.

The acid-resistant film IF may function to prevent the display module DM from being damaged due to an etching solution during etching process. During the etching of the base layer, when the top surface of the display module DM is exposed to the etching solution, damage may be caused to the functional layers included in the display module DM. Attaching the acid-resistant film IF to the top of the display module DM before the etching process, may prevent the display module DM from being damaged by the etching solution. An embodiment of the inventive concept is not limited thereto, and in the method of manufacturing an electronic apparatus according to an embodiment, when the etching of the base layer is omitted, the display module DM may be provided without attaching the acid-resistant film IF.

The acid-resistant film IF may be implemented with transparent resin material, but is not limited thereto. The resin material of the acid-resistant film IF is not particularly limited as long as the material is not dissolved in the etching solution, and may include, for example, polyester, polyester sulfone, triacetyl cellulose, and a cycloolefin polymer.

Referring to FIG. 9B and FIG. 9C, the method of manufacturing an electronic apparatus according to an embodiment may further include etching a bottom surface of the base layer before forming the light-shielding layer.

The base layer BS may include a top surface B-UF and a bottom surface B-LF, which are opposite in the third direction DR3, which is a thickness direction. The top surface B-UF of the base layer BS may be a surface adjacent to the upper panel member DP-U. The bottom surface B-LF of the base layer BS may be a surface opposite to the top surface B-UF of the base layer BS and spaced apart from the upper panel member DP-U.

As illustrated in FIG. 9B, an etching solution ES may be provided on the bottom surface B-LF of the base layer BS. The etching solution ES may etch the bottom surface B-LF of the base layer BS. That is, a portion of the base layer BS may be removed by the etching solution ES. For the top surface B-UF and the bottom surface B-LF of the base layer BS, the bottom surface B-LF exposed to the outside may be etched by coming into contact with the etching solution ES. The upper panel member DP-U disposed above the base layer BS is protected by the acid-resistant film IF, and thus may be prevented from being damaged even when exposed to the etching solution ES. The acid-resistant film IF may be removed from the display module DM after etching the bottom surface B-LF of the base layer.

The etching solution is not particularly limited as long as the solution is capable of etching the base layer, and may include, for example, at least one among hydrofluoric acid, hydrochloric acid, and ammonium fluoride.

During the etching of the bottom surface B-LF of the base layer BS, the thickness of the base layer BS may decrease. As illustrated in FIG. 9B and FIG. 9C, a thickness (d2) of the base layer BS after the etching may be smaller than a thickness (d1) of the base layer BS before the etching. For example, the thickness (d1) of the base layer BS before the etching may be about 0.5 mm, and the thickness (d2) of the base layer BS after the etching may be about 0.2 mm, but an embodiment of the inventive concept is not limited thereto.

Referring to FIG. 9D to FIG. 9F, the method of manufacturing an electronic apparatus according to an embodiment may include forming a light-shielding layer on the rear surface of the base layer.

The forming of the light-shielding layer according to an embodiment may include: forming a preliminary light-shielding layer by providing the ink composition on the rear surface of the display module; and photo-curing the preliminary light-shielding layer.

Referring to FIG. 9D, before providing the ink composition, inverting the display module may be performed. After etching, in a state where the acid-resistant film IF (see FIG. 9C) is removed, the display module DM may be inverted such that the bottom surface B-LF of the base layer BS faces upwards. In the inverted state, the upper panel member DP-U and the panel protecting film PF may be disposed below the base layer BS. In the inverted state, the upper surface B-UF of the base layer BS faces downwards, and the lower surface B-LF of the base layer BS faces upwards, which is the third direction DR3.

After inverting the display module DM, the ink composition IK may be provided onto the bottom surface B-LF of the base layer BS. The base layer BS may serve as a substrate for applying the liquid ink composition IK. The ink composition IK may be provided onto the bottom surface B-LF of the base layer BS in a liquid form before curing. The ink composition IK may be directly provided on the bottom surface B-LF of the base layer BS. In an embodiment, the provision of the ink composition IK may be performed by a screen-printing method.

Thereafter, a light source LL for curing may be provided to the preliminary light-shielding layer P-SL provided by applying the ink composition IK in a predetermined thickness. For example, the light source LL may be ultraviolet light. However, an embodiment of the inventive concept is not limited thereto. The light source LL may be provided over the entire region of the preliminary light-shielding layer P-SL. The preliminary light-shielding layer P-SL may be cured, and eventually, the light-shielding layer SL may be formed as illustrated in FIG. 9G.

The light-shielding layer SL formed by processes shown in FIG. 9A to FIG. 9G may be applied in the above-described electronic apparatus EE (see FIG. 2) in a form of being attached on the rear surface of the display module DM. The display module DM and the light-shielding layer SL manufactured by the processes shown in FIG. 9A to FIG. 9G, may be applied to the electronic apparatus EE (see FIG. 2) according to an embodiment so as to have an arrangement structure shown in FIG. 2 and the like, previously described.

Hereinafter, with reference to Example and Comparative Example, the ink composition according to an embodiment and the display device including the light-shielding layer formed using the same will be specifically described. However, Example and Comparative Example below are exemplified only for helping the understanding of the inventive concept, and the scope of the inventive concept is not limited to Example and Comparative Example below.

### Preparation of Ink Composition

### 1. Example

A pigment, a dispersant, and a first monomer are put in a bead milling instrument and milled and mixed for a specific period of time. A second monomer is additionally put in a firstly mixed pigment dispersion, and is stirred for a predetermined period of time to prepare a mill base composition.

A base resin, a photopolymerizable monomer, and a photo initiator are firstly mixed and stirred for a predetermined period of time, and then the manufactured mill base composition is additionally put to the mixture, and stirred for a predetermined period of time. Thereafter, the mixture is subject to 3-roll milling three times or more to mix components evenly, and the 3-roll milling-completed mixture is subject to a filtering process to filter impurities. In this case, a diameter of the filter is in a range of about 30 m to about 50 m, or may be out of the range. After mixing an antistatic agent into the filtered mixture, proceed with a secondary 3-roll milling three times or more to ensure the antistatic agent is evenly distributed within the ink. Thereafter, additives of a leveling agent, a defoamer, and a coupling agent are additionally mixed and stirred for a predetermined period of time to prepare an ink composition.

### 2. Comparative Example

Compared to the ink composition according to Example, an ink composition according to Comparative Example are manufactured in the same manner as Example except that as a pigment carbon black powder is used in place of the mill base composition.

Each composition ratio of the ink compositions according to Example and Comparative Example is listed in Table 1 below. A unit indicating an amount of each composition in Table 1 represents parts by weight of each composition, with respect to the total parts by weight of the ink composition.

The mill base used in the ink composition according to Example includes about 5 wt % to about 30 wt % of pigment, about 2 wt % to about 10 wt % of dispersant, about 30 wt % to about 45 wt % of first monomer, and about 30 wt % to about 45 wt % of second monomer. In the mill base, carbon black was used as the pigment, 1,6-hexanediol diacrylate was used as the first monomer, and pentaerythritol tetraacrylate was used as the second monomer. Pentaerythritol tetraacrylate was used as the photo polymerizable monomer. A viscosity of 1,6-hexanediol diacrylate is about 10 cP, and a viscosity of pentaerythritol tetraacrylate is about 1100 cP.

TABLE 1

| Classification | Examples | Comparative Examples |
|---|---|---|
| Base resin | 47 | 42 |
| Photo initiator | 10 | 10 |
| Photo polymerizable monomer | 30.8 | 44 |
| Mill base | 10 | — |
| Carbon black powder | — | 1.8 |
| Coupling agent | 1 | 1 |
| Antistatic agent | 0.2 | 0.2 |
| Leveling agent | 0.5 | 0.5 |
| Defoamer | 0.5 | 0.5 |

### (Evaluation of Properties of Light-Shielding Layer)

The ink compositions according to Example and Comparative Example were cured to manufacture light-shielding layer, and properties of the light-shielding layer were evaluated, and the evaluation result is listed in Table 2 below. Properties of the manufactured light-shielding layer were evaluated by the following methods.

### 1. Adhesion

Adhesion was evaluated using the ASTM D3359 method. ASTM is a method for measuring the adhesion of a thin film, where the film formed on the substrate is cut into a cross-hatch pattern, tape is applied and then removed to measure the adhesion of the film. If the thin film adheres to the tape and the substrate is largely exposed after the tape is removed, the thin film has poor adhesion. On the contrary, if the thin film remains on the substrate after the tape is removed, the thin film has excellent adhesion.

On the basis of a cut area of the cross-hatch pattern formed in the thin film, when the thin film remains intact without removal, when about 5% or less of the thin film over the cross-hatch area is removed, when about 5% to about 15% of the thin film over the cross-hatch area is removed, when about 15% to about 35% of the thin film over the cross-hatch area is removed, when about 35% to about 65% of the thin film over the cross-hatch area is removed, and when about 65% or more of the thin film over the cross-hatch area is removed, the adhesion in each case is referred to as 5B, 4B, 3B, 2B, 1B, and 0B. According to the above classification, 5B means that the adhesion is excellent, and 0 means that the adhesion of the thin film is poor.

### 2. Storage Stability

After leaving the ink composition at room temperature (about 25° C.), the time until changes such as a phase separation, or agglomeration occurred was measured.

### 3. Surface Roughness

Surface roughness was evaluated using images scanned by a scanning electron microscope (SEM) of the cross-section of the coating layer.

TABLE 2

| Classification | Examples | Comparative Examples |
|---|---|---|
| Thickness (μm) | 12 | 12 |
| Adhesion | 5B | 4B |
| Storage stability (time) | 16 | 7 |
| Surface roughness (μm) | 2.5 | 4.3 |

Referring to Table 2, it can be confirmed that the light-shielding layer formed from the ink composition according to Example of the inventive concept has excellent adhesion and storage stability, and has a decrease in surface roughness, compared to the light-shielding layer formed from the ink composition according to Comparative Example. On the contrary, the ink composition according to Comparative Example in which carbon black is mixed in a powder form, has reduced dispersibility in the composition, and thus storage stability decreases due to an agglomeration phenomenon of the piment and the like. Therefore, the light-shielding layer formed using the ink composition according to Comparative has reduced adhesion and increased surface roughness, compared to the light-shielding layer according to Example. As a result, referring to Table to, it can be confirmed that the ink composition according to an embodiment has excellent storage stability and thus may form the light-shielding layer having improved durability and reliability. In addition, a display including the light-shielding layer formed using the ink composition according to an embodiment may also have improved durability and reliability.

### (Evaluation of Display Device)

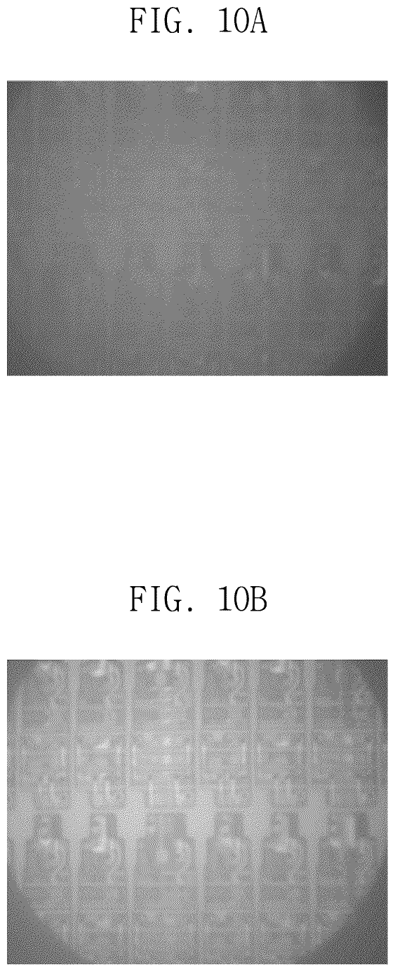

FIG. 10A is an image of the display device including the light-shielding layer according to Comparative Example, as captured by an infrared camera. FIG. 10B is an image of the display device including the light-shielding layer according to Example, as captured by an infrared camera. Hereinafter, referring to the evaluation results in Table 3, the display device including the light-shielding layer formed using the ink composition according to an embodiment will be specifically described.

A pixel repair success rate of the display device including the light-shielding layer formed using the ink composition according to an embodiment of the inventive concept was evaluated, and the evaluation result is listed in Table 3 below. The pixel repair success rate includes the determination of defects in the manufactured display device and a repair process of the detected defective pixels. For evaluation of the pixel repair success rate, defectiveness of the display device is determined by providing infrared light from the lower side of the manufactured display device. Therefore, as infrared light transmittance increases, the pixel repair success rate also increases.

TABLE 3

| Classification | Examples | Comparative Examples |
|---|---|---|
| Pixel repair success rate (%) | 78 | 19 |

Referring to Table 3, it can be confirmed that a pixel repair success rate for the display devices according to Example is significantly improved than a pixel repair success rate for the display devices according to Comparative Example. Referring to FIG. 10A and Table 3, when the light-shielding layer is formed using the ink composition including carbon black powder, low light transmittance for infrared light is shown. Accordingly, after manufacturing the display device, it is difficult to determine the defectiveness of the display module from the lower side of the light-shielding layer, which results in a decrease in the pixel repair success rate

On the contrary, referring to FIG. 10B and Table 3, the light-shielding layer included in the display device of Example has high transmittance for infrared light, and after forming the light-shielding layer below the display module, it is easy to determine the defectiveness of the display module from the lower side. The light-shielding layer formed from the ink composition according to an embodiment has high transmittance for infrared light. Therefore, it may be easy to view whether the display module has defectiveness or not by providing infrared light from the lower side of the light-shielding layer. Therefore, re-processibility may be improved by easily viewing and determining the defectiveness of the display module during the manufacture of the display device.

The light-shielding layer formed using the ink composition according to an embodiment may have excellent light-shielding properties, durability, adhesion, etc. In addition, the electronic apparatus including the light-shielding layer formed using the ink composition according to an embodiment may have improved durability and reliability.

Hitherto, although the embodiments of the present invention have been described, it is understood that the present invention should not be limited to these embodiments but various changes and modifications can be made by one ordinary skilled in the art within the spirit and scope of the present invention as hereinafter claimed. Therefore, the technical scope of the inventive concept is not intended to be limited to the contents set forth in the detailed description of the specification, but is intended to be defined by the appended claims.

What is claimed is:

1. An ink composition comprising:
a base resin;
a photo initiator; and
a mill base comprising a pigment, a dispersant, and a (meth)acrylate monomer,
wherein the (meth)acrylate monomer comprises:
a first monomer having a first viscosity; and
a second monomer having a second viscosity greater than the first viscosity.

2. The ink composition of claim 1,
wherein with respect to total amount 100 wt % of the mill base,
the mill base comprises:
about 5 wt % to about 30 wt % of the pigment;
about 2 wt % to about 10 wt % of the dispersant;
about 30 wt % to about 45 wt % of the first monomer; and
about 30 wt % to about 45 wt % of the second monomer.

3. The ink composition of claim 1, wherein a difference between the first viscosity and the second viscosity is about 100 cP to about 5000 cP.

4. The ink composition of claim 1, wherein the pigment comprises carbon black.

5. The ink composition of claim 1, wherein the ink composition comprises no solvent.

6. The ink composition of claim 1,
wherein the first monomer comprises 1,6-hexanediol diacrylate, and
the second monomer comprises pentaerythritol tetraacrylate.

7. The composition of claim 1, further comprising:
a photo polymerizable monomer including two or more polymerizable groups;
a coupling agent; and
an additive including at least one among an antistatic agent, a leveling agent, and a defoamer.

8. The ink composition of claim 7,
wherein, with respect to the total content of the ink composition,
the ink composition comprises:
about 25 wt % to about 60 wt % of the base resin;
about 5 wt % to about 15 wt % of the photo initiator;
about 5 wt % to about 20 wt % of the mill base;
about 25 wt % to about 60 wt % of the photopolymerizable monomer;
about 0.5 wt % to about 3 wt % of the coupling agent; and
about 0.2 wt % to about 4 wt % of the additive.

9. The ink composition of claim 7, wherein the second monomer is the same as the polymerizable monomer.

10. The ink composition of claim 1, wherein the base resin has a weight average molecular weight of about 5000 to about 50000.

11. An electronic apparatus comprising:
a display module;
a light-shielding layer disposed below the display module and formed using an ink composition; and
a housing accommodating the display module,
wherein the ink composition comprises:
a base resin;
a photo initiator; and
a mill base including a pigment, a dispersant, and a (meth)acrylate monomer, and
the (meth)acrylate monomer comprises:
a first monomer having a first viscosity; and
a second monomer having a second viscosity greater than the first viscosity.

12. The electronic apparatus of claim 11, wherein the light-shielding layer has a thickness of about 9 m to about 16 m.

13. The electronic apparatus of claim 11,
wherein the display module comprises:
a base layer; and
a display element layer disposed on the base layer and including a light-emitting element, and
the light-shielding layer is directly disposed below the base layer.

14. The electronic apparatus of claim 11, wherein the light-shielding layer is a single layer formed using the ink composition.

15. A method of manufacturing an electronic apparatus comprising:
providing a display module; and
providing an ink composition on a rear surface of the display module to form a light-shielding layer,
wherein the ink composition comprises:
a base resin;
a photo initiator; and
a mill base including a pigment, a dispersant, and a (meth)acrylate monomer,
the (meth)acrylate monomer comprises:
a first monomer having a first viscosity; and
a second monomer having a second viscosity greater than the first viscosity.

16. The method of claim 15, further comprising preparing the ink composition,
wherein, the preparation of the ink composition comprises:
milling a mixture of the pigment, the dispersant, and the first monomer to prepare a first mill base composition;
preparing a second mill base composition including the second monomer; and
mixing the first mill base composition and the second mill base composition to prepare the mill base.

17. The method of claim 15,
wherein the forming of the light-shielding layer comprises:
providing the ink composition on the rear surface of the display module to form a preliminary light-shielding layer; and
photo-curing the preliminary light-shielding layer.

18. The method of claim 17, wherein the providing of the ink composition is performed by a screen-printing method.

19. The method of claim 15,
wherein the display module comprises:
a base layer; and
a display element layer disposed on the base layer and including a light-emitting element, and
the light-shielding layer is directly formed below the base layer.

20. The method of claim 19,
wherein the base layer comprises a glass substrate,
before the forming of the light-shielding layer, etching a bottom surface of the base layer spaced apart from the display element layer is further comprised, and
in the forming of the light-shielding layer, the ink composition is applied onto the etched bottom surface of the base layer.
